(19) United States
(12) Patent Application Publication
(10) Pub. No.: US 2008/0102605 A1
(43) Pub. Date: May 1, 2008

(54) Method and Apparatus for Forming a Silicon Wafer

(75) Inventors: Leo van Glabbeek, Franklin, MA (US); Brian Atchley, San Mateo, CA (US); Robert E. Janoch, Westford, MA (US); Andrew P. Anselmo, Arlington, MA (US); Scott Reitsma, Shrewsbury, MA (US)

Correspondence Address: BROMBERG & SUNSTEIN LLP, 125 SUMMER STREET, BOSTON, MA, 02110-1618, US

(73) Assignee: EVERGREEN SOLAR, INC., Marlborough, MA (US)

(21) Appl. No.: 11/925,169

(22) Filed: Oct. 26, 2007

Related U.S. Application Data
(60) Provisional application No. 60/854,849, filed on Oct. 27, 2006.
(60) Provisional application No. 60/938,792, filed on May 18, 2007.

(51) Int. Cl. C30B 35/00; H01L 21/78

(52) U.S. Cl. 438/463; 117/205; 257/E21.599

(57) ABSTRACT

A furnace for growing a ribbon crystal has a channel for growing a ribbon crystal at a given rate in a given direction, and a separating mechanism for separating a portion from the growing ribbon crystal. At least a part of the separating mechanism moves at about the given rate and in about the given direction while separating the portion from the growing ribbon crystal.

### PRIORITY

This patent application claims priority from provisional U.S. patent application No. 60/854,849 filed Oct. 27, 2006, entitled, “FORMING, CUTTING AND PROCESSING SEMICONDUCTOR WAFERS,” and naming Robert E. Janoch Jr. as inventor, the disclosure of which is incorporated herein, in its entirety, by reference.

This patent application claims also priority from provisional U.S. patent application No. 60/938,792 filed May 18, 2007, entitled, “METHOD AND APPARATUS FOR FORMING A SILICON WAFER,” and naming Leo van Glabbeek, Brian Atchley, Robert E. Janoch Jr., Andrew P. Anselmo, and Scott Reitsma as inventors, the disclosure of which is incorporated herein, in its entirety, by reference.

### FIELD OF THE INVENTION

The invention generally relates to semiconductor wafers and, more particularly, the invention relates to forming semiconductor wafers.

### BACKGROUND OF THE INVENTION

Silicon wafers are the building blocks of a wide variety of semiconductor devices, such as solar cells, integrated circuits, and MEMS devices. For example, Evergreen Solar, Inc. of Marlboro, Mass. forms solar cells from silicon wafers fabricated by means of the well-known “ribbon pulling” technique.

The ribbon pulling technique undesirably requires significant human interaction. Specifically, to produce individual silicon wafers using the ribbon pulling technique, an operator first manually scribes a semiconductor ribbon crystal with a diamond point, and then places the cut portion (now considered to be a “wafer”) on a plastic tray for processing in a separate laser apparatus that is spaced from the furnace growing the ribbon crystals. The laser apparatus then further cuts the (larger) wafer into smaller semiconductor wafers. For example, the laser may cut a two meter long wafer into one or more 15 centimeter long rectangular smaller semiconductor wafers.

In addition to being labor intensive, manual scribing and handling of semiconductor ribbon crystals and wafers can reduce wafer yield. In particular, scribing and handling undesirably can form microscopic cracks at the edges of the ribbon crystals and wafers. Among other things, microscopic cracks ultimately often lead to macroscopic cracks and, eventually, wafer failure.

### SUMMARY OF THE INVENTION

In accordance with one embodiment of the invention, a furnace for growing a ribbon crystal has a channel for growing a ribbon crystal at a given rate in a given direction, and a separating mechanism for separating a portion from the growing ribbon crystal. At least a part of the separating mechanism moves at about the given rate and in about the given direction while separating the portion from the growing ribbon crystal.

The separating mechanism may have a fiber laser that produces a short pulsed laser beam for cutting the growing ribbon crystal. Alternatively, or in addition, the separating mechanism may have a laser beam directing apparatus for directing a laser beam toward the growing ribbon crystal. In both instances, the laser beam may be considered to be a part of the separating mechanism.

To improve output volume, the apparatus has a plurality of channels and thus, may be capable of growing a plurality of ribbon crystals. In that case, the separating mechanism may be movable to cut each of the plurality of ribbon crystals in substantially the same manner. Moreover, the separating mechanism may have two areas for grasping the growing ribbon crystal. In this case, the separating mechanism may separate the crystal portion between the two grasping areas. The separating mechanism also may have a movable arm for moving the separated portion of the ribbon crystal from a first location to a second location.

In some embodiments, the separating mechanism has an input for receiving movement information relating to the given rate of the growing ribbon crystal. The above noted part of the separating mechanism may move at about the given rate in response to receipt of the movement information. To further improve efficiency and yield, the separating portion may cut the ribbon crystal as a function of the compression and tension of the growing ribbon crystal. After cutting the separated portion, the furnace may place it in a container.

In accordance with another embodiment of the invention, an apparatus for growing a ribbon crystal has a crystal growth channel, a movable arm for grasping a growing ribbon crystal, and a laser separation apparatus for separating a portion from the growing ribbon crystal.

The above noted apparatus may also have a plurality of ribbon guides for guiding a plurality of growing ribbon crystals. The laser separation apparatus (e.g., a laser, a guide for a laser beam, or the beam itself) may be movable to each of the guides for cutting a plurality of growing ribbon crystals in substantially the same manner.

In accordance with other embodiments of the invention, a method of forming a wafer grows a ribbon crystal from a molten material, and uses a separation mechanism for cutting the growing ribbon crystal to produce a separated portion. Next, the method controls a movable arm to move the separated portion to a receptacle.

Among other ways, the method may use a separation mechanism that forms a generally linear cut line across the ribbon crystal between first and second suction devices. In various embodiments, the method may grow a plurality of ribbon crystals from the molten material. To do this, the method may then detect which of the plurality of ribbon crystals is at least a given length, and serially move the separation mechanism to each of a plurality of ribbon crystals determined to be at least the given length.

The separation mechanism may produce a laser beam that moves in at least a first direction across the growing ribbon crystal, and a second direction that is substantially perpendicular to the first direction. The laser beam may move in the second direction at a rate that is substantially the same as the growth rate of the growing ribbon crystal in the second direction.

In accordance with yet other embodiments, an apparatus for growing a ribbon crystal has a channel for growing a ribbon crystal, and a movable arm for grasping a growing ribbon crystal. The apparatus also has a plurality of channels for substantially simultaneously growing a plurality of separate ribbon crystals, and a separation apparatus for separating a portion from the growing ribbon crystal. The separation apparatus is movable to process ribbon crystals at two or more of the channels.

The apparatus having a plurality of channels may also have position logic capable of detecting the position of at least one ribbon crystal. The separation apparatus is movable to process selected ones of the plurality of growing ribbon crystals in response to receipt of a signal from the position logic.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a ribbon pulling furnace configured in accordance with illustrative embodiments of the invention. This figure also shows steps 200, 202, and 204 of the process shown in FIG. 2.

FIG. 2 shows a process of forming a semiconductor wafer in accordance with illustrative embodiments of the invention.

FIG. 3 schematically shows the furnace of FIG. 2 between step 206 and step 208.

FIG. 4 schematically shows the furnace of FIG. 2 when executing step 210.

FIG. 5 schematically shows the furnace of FIG. 2 when executing step 212.

FIG. 6 schematically shows additional details of an enclosure used in the furnace of FIG. 2.

FIG. 7 shows a chart detailing a number of different options for implementing various embodiments the invention.

FIGS. 8-11 schematically show several permutations from a chart of FIG. 7 in accordance with illustrative embodiments of the invention.

### DESCRIPTION OF ILLUSTRATIVE EMBODIMENTS

In illustrative embodiments, a method of forming a silicon ribbon wafer enables substantially continuous wafer production while minimizing human intervention. To that end, an illustrative ribbon pulling furnace may have a separating mechanism that, while separating (e.g., cutting), moves at about the same rate and in about the same direction as the growing ribbon crystal it is processing. Among other things, the separating mechanism may have a laser apparatus, and/or may be capable of processing a plurality of ribbon crystals growing simultaneously either in a single furnace, or in a plurality of furnaces. Details of these and other embodiments are discussed below.

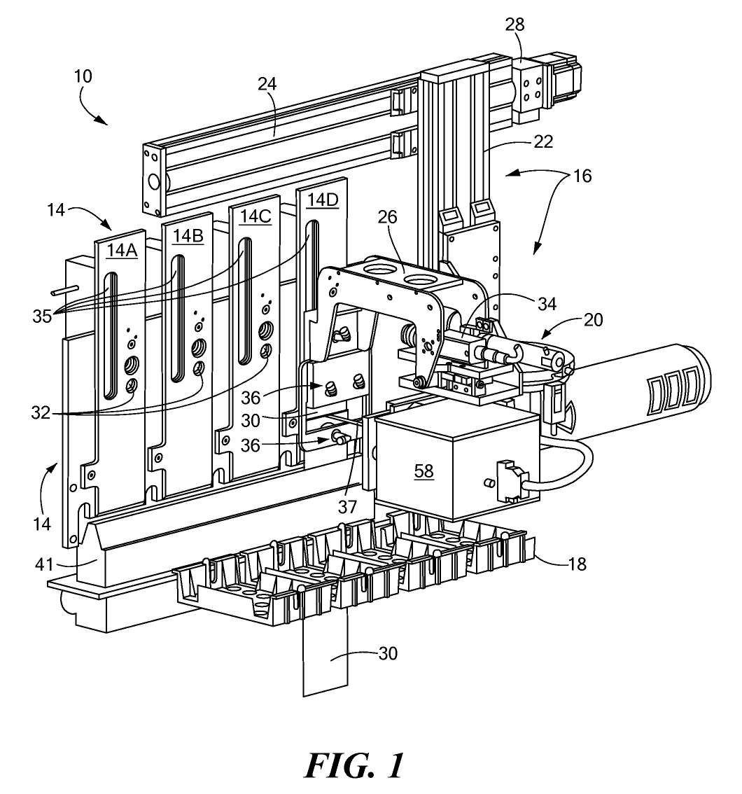

FIG. 1 schematically shows a ribbon pulling furnace 10 configured in accordance with illustrative embodiments of the invention. Among other things, the furnace 10 has a crucible (not shown) for containing molten material, and a ribbon guide assembly 14 with four guides 14A-14D for guiding four separate ribbon crystals 30, along four separate growth channels, from the molten material.

For simplicity, the molten material discussed herein may be molten silicon. Of course, various embodiments of the invention may be applied to other molten materials. Moreover, those skilled in the art should understand that principles of various embodiments apply to furnaces that process more or fewer than four separate ribbon crystals (generally identified by reference number 30). For example, some embodiments apply to furnaces growing a single ribbon crystal 30 only, or six ribbon crystals 30. Accordingly, discussion of a single furnace growing four ribbon crystals 30 is for illustrative purposes only.

In accordance with illustrative embodiments of the invention, the furnace 10 has a movable assembly 16 for selectively separating (e.g., cutting) growing ribbon crystals 30, and then moving the separated portion (now in wafer form since it is no longer growing), which forms a smaller wafer (referred to herein simply as a “wafer 31”), into a conventional tray 18. For example, the movable assembly 16 may process a first ribbon crystal 30 by 1) separating a portion from the first ribbon crystal 30 as it grows, and then 2) placing the separated portion in the tray 18. After placing the separated portion of the first ribbon crystal 30 in the tray 18, the movable assembly 16 may repeat the same process with a second growing ribbon crystal 30. This process may repeat indefinitely between the four growing ribbon crystals 30 until some shut down or stoppage event (e.g., to clean the furnace 10).

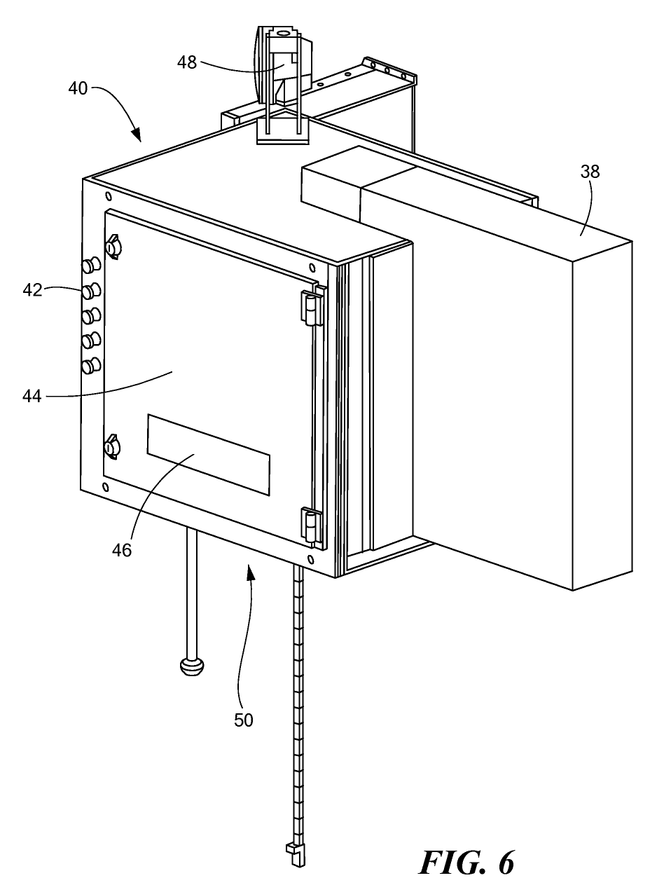

To perform this function, the movable assembly 16 has, among other things, a separation mechanism/apparatus (e.g., having a laser assembly 20, discussed immediately below but shown in FIG. 6) for separating a portion of the ribbon crystal 30, and a rotatable robotic arm 26 for grasping both wafers 31 and growing ribbon crystals 30, and positioning the grasped wafers 31 in the tray 18. Consequently, the furnace 10 may substantially continuously produce silicon wafers 31 without interrupting the crystal growth process. Some embodiments, however, can cut the ribbon crystals 30 when crystal growth has stopped.

To those ends, the separation apparatus may include a laser assembly 20 that, along with the rest of the movable assembly 16, is vertically movable along a vertical stage 22, and horizontally movable along a horizontal stage 24. Conventional motorized devices, such as stepper motors (one of which is shown and identified by reference number 28), control movement of the movable assembly 16. For example, a vertical stepper motor (not shown) vertically moves the movable assembly 16 as a function of the vertical movement of a growing ribbon (discussed in greater detail below). A horizontal stepper motor 28 moves the assembly 16 horizontally. Of course, as noted, other types of motors may be used and thus, discussion of stepper motors is illustrative and not intended to limit all embodiments.

The flexibility afforded by the vertical and horizontal stages 22 and 24 enables the laser assembly 20 to serially cut multiple growing ribbon crystals 30. In illustrative embodiments, the vertical and horizontal stages 22 and 24 are formed primarily from aluminum members that are isolated from the silicon, which can be abrasive. Specifically, exposing the stages 22 and 24 to silicon could impair and degrade their functionality. Accordingly, illustrative embodiments seal and pressurize the stages 22 and 24 to isolate them from the silicon in their environment.

As noted above, the ribbon guide assembly 14 has four separate guides 14A-14D (i.e., one for each growth channel) for simultaneously growing four separate ribbon crystals 30. When referenced individually or collectively without regard to a specific channel, a guide will be generally identified by reference number 14.

Each guide 14, which is formed primarily from graphite, produces a very light vacuum along its face. This vacuum causes the growing ribbon crystal 30 to slide gently along the face of the guide 14 to prevent the ribbon crystal 30 from drooping forward. To that end, illustrative embodiments provide a port on the face of each guide 14 for generating a Bernoulli vacuum having a pressure on the order of about 1 inch of water.

Each guide 14 also has a ribbon detect sensor 32 for detecting when the growing ribbon crystal 30 reaches a certain height/length. As discussed below, the detect sensors 32 each produce a signal that controls processing by, and positioning of, the movable assembly 16. Specifically, after detecting that a given ribbon crystal 30 has reached a certain height/length, the detect sensor 32 on a given guide 14 monitoring the given ribbon crystal 30 forwards a prescribed signal to logic that controls the movable assembly 16. After receipt, the movable assembly 16 should move horizontally to the given guide 14 to produce a wafer 31. Of course, the movable assembly 16 may be delayed if requests from sensors 32 at other guides 14/channels have not been sufficiently serviced.

Many different types of devices may be used to implement the functionality of the detect sensor 32. For example, a retro-reflective sensor, which transmits an optical signal and measures resultant optical reflections, should provide satisfactory results. As another example, an optical sensor having separate transmit and receive ports also may implement the detect sensor functionality. Other embodiments may implement non-optical sensors.

The movable assembly 16 therefore moves to the appropriate guide 14 in response to detection by the detect sensor 32. In this manner, the movable assembly 16 is capable of serially processing and cutting the four growing ribbon crystals 30. It should be noted that illustrative embodiments apply to other configurations and, as suggested above, to different numbers of guides 14/channels. Discussion of four side-by-side guides 14 thus is for illustrative purposes only.

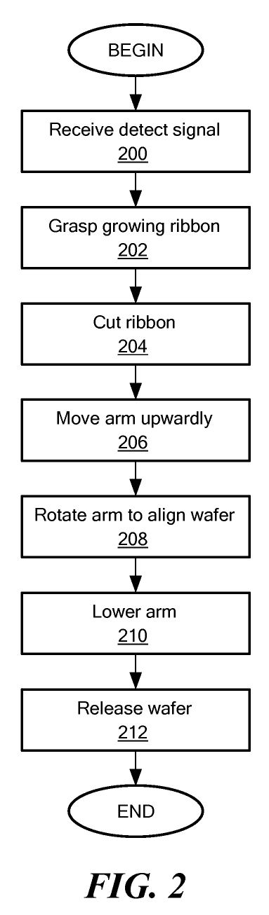

FIG. 2 shows a general process of forming a ribbon crystal-based silicon wafer 31 in accordance with illustrative embodiments of the invention. It should be noted that this process shows a few of the many steps of forming a ribbon crystal-based silicon wafer 31. Accordingly, discussion of this process should not be considered to include all necessary steps.

The process begins at step 200, in which the detect sensor 32 in one of the channels determines that its ribbon crystal 30 has reached a minimum height. For example, the detect sensor 32 of a given channel may be fixedly positioned approximately six feet above the liquid/solid interface in the crucible. Accordingly, when the growing ribbon crystal 30 is approximately 30 centimeters long, the detect sensor 32 forwards the above noted prescribed signal to logic that, sometime after receipt, causes the movable assembly 16 (i.e., the robotic arm 26 and laser assembly 20, among other things) to move into position at the given channel.

After arriving at the relevant channel, the robotic arm 26 grasps the ribbon crystal 30 as shown in FIG. 1 (step 202). To that end, the movable assembly 16 has a conventional vision system for detecting the edge of the growing ribbon crystal 30. In illustrative embodiments, the vision system includes a ribbon edge detect camera 34, a backlight area 35 for improving contrast for the camera 34, and logic for determining the leading edge of the ribbon crystal 30 from a digital image/picture produced by the camera 34. In illustrative embodiments, the backlight area 35 comprises a plurality of light emitting diodes, while the logic includes a software program.

For grasping purposes, the robotic arm 26 has at least three suction areas 36 for securing with a ribbon crystal 30 by means of a vacuum (referred to as a “grasping vacuum”). Before applying the grasping vacuum, however, the robotic arm 26 moves so that the three suction areas 36 are positioned very close to the front facing face of the growing ribbon crystal 30. For example, the suction areas 36 initially may be positioned about 0.125 inches away from the front face of the growing ribbon crystal 30.

As known by those skilled in the art, ribbon crystals 30 are extremely fragile. Application of the grasping vacuum at this time thus may cause the ribbon crystal 30 to strike the suction areas 36 with a force that can damage the ribbon crystal 30. In an effort to reduce the likelihood of this possibility, illustrative embodiments gently urge the ribbon crystal 30 toward the suction areas 36 before applying the noted grasping vacuum. Specifically, illustrative embodiments stop applying the Bernoulli vacuum to the back face of the growing ribbon crystal 30. Instead, a timed valve on the front face of the guide 14 applies a very light positive pressure to the backside of the ribbon crystal 30. This combination of forces should urge the ribbon crystal 30 to gently contact or almost contact the suction areas 36 (i.e., closing the small gap), at which time the furnace 10 may begin applying the noted grasping vacuum.

To ensure stability, one of the suction areas 36 is vertically lower than the other two suction areas 36. The suction areas 36 each may include an apparatus (not shown in detail) with a bellows-type suction cup using an external vacuum source. The point of contact between the ribbon crystal 30 and the suction cups preferably is relatively soft to minimize contact force between the wafer 31 and suction apparatus.

After grasping one of the ribbon crystals 30, the process continues by horizontally cutting the it as shown in FIG. 1 between upper and lower suction areas 36 (step 204). In illustrative embodiments, a laser 37 (with a scanner 58), such as a fiber laser, generates a laser beam 37 that cuts across the ribbon crystal 30 in a predefined manner to produce a wafer 31.

For example, after the camera 34 takes a digital picture of the growing ribbon crystal 30, the software may determine which pixels in the digital picture represent the leading edge of the growing ribbon crystal 30. Among other ways, the leading edge may take on the appearance of a contrasting row of black pixels in the picture. The software then translates the position of the leading edge within the digital picture to a value representing the physical position of the ribbon crystal edge along the guide 14.

This generated value enables the laser 37 to aim its beam at the appropriate location of the growing ribbon crystal 30. This position may be a set distance below the leading edge. For example, this position may be about 15 centimeters below the leading edge and thus, meet certain size specifications without further processing.

Moreover, as known by those skilled in the art, a silicon ribbon crystal 30 has portions that are under compression (near the middle of the ribbon crystal 30), and other portions that are under tension (near the edges of the ribbon crystal 30). These disparate portions generally are in the same horizontal plane.

To minimize fracturing while cutting, illustrative embodiments first cut through the portions under compression, and then through the portions under tension.

For example, logic associated with the laser assembly 20 may be configured to cut an 82 millimeter wide ribbon crystal 30 first through the middle 65 millimeters (the portion generally the portion under compression), and then through the remaining uncut portions (the portions generally the portions under tension). The laser 38 may cut through the two portions under tension either at the same time (i.e., using the same pass), or serially (using different passes).

To cut through a ribbon crystal 30 in that manner, the laser 38 may have a scanner that makes multiple passes across the portion under compression before cutting through portions under tension. In so doing, the laser 38 sequentially cuts through each different type of portion. When using a low power pulse laser 38, each pass produces a set of holes. The movable laser assembly 20 is programmed, however, to produce holes on each pass that are offset from at least those of the previous pass and other passes. Accordingly, the laser 38 cuts through a silicon ribbon crystal 30 having a thickness of about 150-300 microns after a plurality of passes.

For example, the laser 38 may produce 100 nanosecond pulses at a rate of 20 kilohertz and may move horizontally at a rate of about 2 meters per second. Such a laser 38 may make about 300 passes to cut through the portion of the silicon ribbon crystal 30 under compression. To complete the cut through the ribbon crystal 30, the laser 38 repeats the multi-pass process for portions under tension. Using a multiple pass process substantially minimizes heat produced by the cutting process, thereby improving results.

Alternative embodiments of the laser cut the ribbon 30 straight across the width of the ribbon 30 without regard to compression or tension regions. To minimize microcracks and other related problems, however, such embodiments preferably still use a multipass method similar to that discussed above.

In illustrative embodiments, the laser 38 is a low power, fiber laser that produces a pulsed laser beam 37 (scanning beam 37). For example, the laser 38 may be a RSM PowerLine F fiber laser, distributed by Rofin-Sinar Laser GmbH, of Starnberg, Germany. The PowerLine F fiber laser is a q-switched Yb fiber laser operating at about 1065 nm. After testing, the inventors were surprised to learn that, based on the performance of the noted Rofin laser, low power lasers (i.e., those using the multiple scans as discussed above) produced substantially no microcracks of concern and yet cut quickly enough to work effectively and efficiently in an automated system. For example, the inventors have successfully used low power lasers 38 in four channel systems that grow the ribbon crystals 30 at a rate of about 18 millimeters per minute. During testing, a low power laser 38 that takes about 40 seconds to completely cut through a growing ribbon crystal 30 moves between the channels to produce silicon wafers 31 efficiently and continuously.

Of course, other brands and types of lasers 38 may be used. For example, alternative embodiments may use higher power lasers 38, which require only one or two passes. Such lasers 38, however, undesirably can generate excessive heat and can create microcracks in the resultant wafer 31.

Rather than making a substantially straight cut across a ribbon crystal 30, some embodiments cut the ribbon crystal 30 in a manner that forms specific edge features (e.g., chamfers). Among other things, the edge features may include rounded corners that further reduce wafer stress.

It should be noted that various embodiments use a number of other laser implementations. For example, a furnace 10 may have a single, stationary laser 38 and a movable fiber optic cable 57 (FIG. 11, discussed below) that terminates at a movable scanner 58. As another example, each ribbon guide 14 may have its own laser 38, or each ribbon guide 14 may have a single laser head that receives energy from a single laser 38 (discussed below). Rather than use fiber optic cable, some embodiments simply use air as the laser transmission medium. Accordingly, in some embodiments, the laser beam 37 itself may be considered to be part of the movable assembly 16. Moreover, some embodiments may use other techniques for cutting the ribbon crystal 30, such as manual saws or scoring devices.

As can be reasonably discerned by FIG. 1, until the grasping vacuum is no longer applied through the suction areas 36, the movable assembly 16 and ribbon crystal 30 move at about the same rate and in the same direction—there is substantially no relative movement between the two bodies. By doing this, the growth process continues even while the laser 38 cuts the ribbon crystal 30. In addition, unless preconfigured otherwise, the cut across the ribbon crystal 30 should be substantially straight. Illustrative embodiments therefore vertically position the suction areas 36 relative to the ribbon crystal 30 (e.g., relative to the leading edge of the ribbon crystal 30) in a manner that ensures a specific size for the ultimately formed wafer 31 (e.g., 15 centimeters). Among other things, this vertical position thus is a function of the crystal growth rate and the length of time the movable assembly 16 takes to grasp the ribbon crystal 30.

Specifically, illustrative embodiments determine the actual growth rate of the ribbon crystal 30 many times per second (e.g., 200 times per second). At about the moment that the suction areas 36 apply the grasping vacuum, logic receiving this growth rate information clamps the speed/rate of the movable assembly 16 to a substantially constant rate equal to that growth rate at this time. Of course, at this point, the movable assembly 16 also moves in the same direction as the growing ribbon crystal 30.

Cutting in this manner should produce ribbon crystal-based wafers 31 having substantially uniform lengths with a minimum of microcracks. In alternative embodiments, however, before grasping the growing ribbon crystal 30, the movable assembly 16 moves to a fixed location relative to the furnace 10. Such embodiment is unlike the first noted embodiment because it does not position the movable assembly 16 relative to the growing ribbon crystal 30. Although such embodiments still move at the above noted determined rate after grasping the ribbon crystal 30, they may not necessarily produce substantially uniformly sized wafers 31.

During testing, the inventors noticed that the laser beam 37 began oxidizing portions of the ribbon crystal 30 and, consequently, the resultant wafers 31. To minimize this effect, some embodiments add a shielding gas to the region of the furnace 10 cutting the ribbon crystal 30. Among other things, the shielding gas may be argon.

After cutting the ribbon crystal 30, the robotic arm 26 moves vertically upwardly a very small distance (e.g., 0.125 inches) to ensure complete separation between the removed portion (i.e., the wafer 31) and the remaining ribbon crystal 30 (step 206). If the separation is not complete, the method may cause the laser 38 again to cut across to the ribbon crystal 30 in the unseparated area, or across the entire width of the ribbon crystal 30 (in the same area that previously was cut).

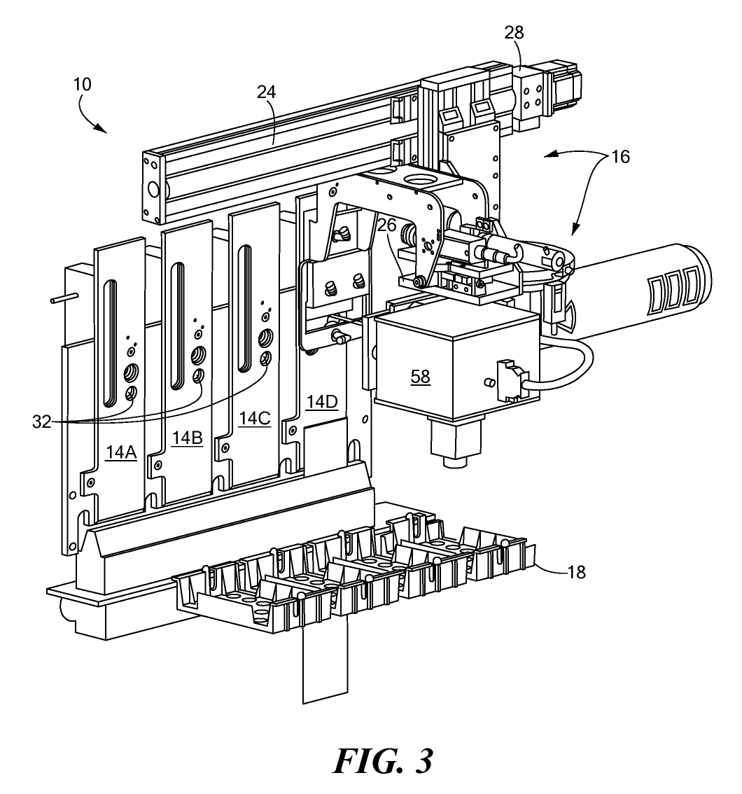

Next, the movable assembly 16 moves upwardly a greater distance to provide enough clearance for rotating the arm 26 (FIG. 3). At some point before this time, the grasping vacuum applied to the remaining portion of the ribbon crystal 30 should be released. The grasping vacuum applied to the newly cut wafer 31, however, should continue to be applied.

In addition, to provide further clearance, the robotic arm 26 may move in a direction generally normal to the face of the ribbon crystal 30. For example, the robotic arm 26 may move about 20 millimeters away from the face of the ribbon crystal 30.

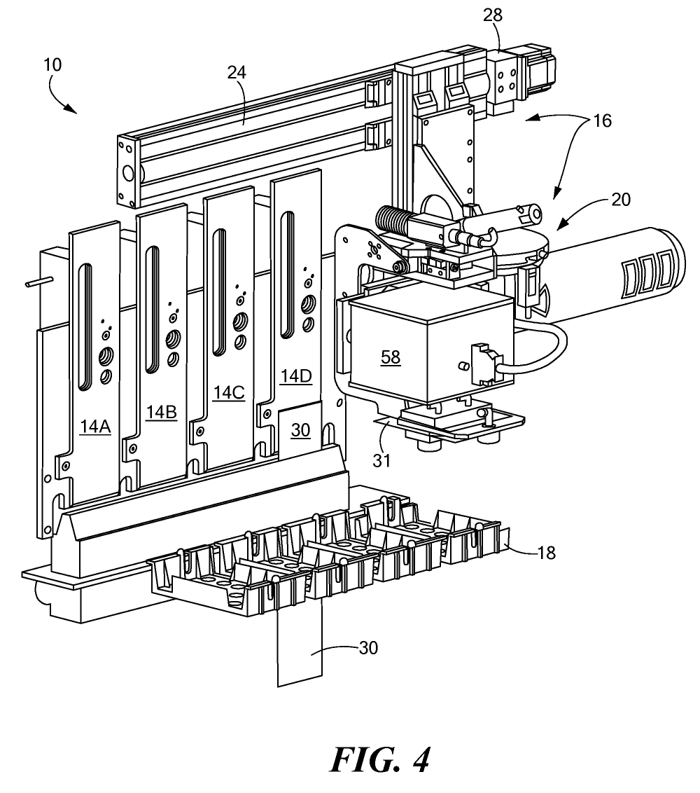

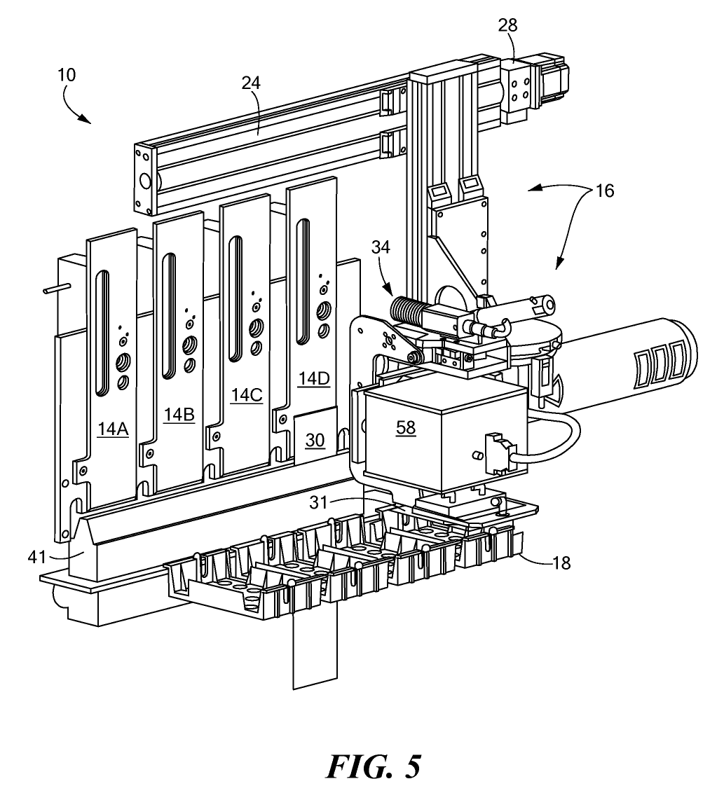

After providing the appropriate clearance, the process then continues to step 208, which rotates the arm 26 about ninety degrees to align the wafer 31 with the underlying tray 18 (FIG. 4). The stepper motor then lowers the robotic arm 26 (step 210, FIG. 5) to a cavity in the tray 18. At this point, the grasping vacuum may be released, thus permitting the wafer 31 to fall gently onto the tray 18 (step 212). To minimize the impact of the fall, the wafer 31 should be very close to the tray 18 before it is released. In addition, the tray 18 can have features to minimize impact (e.g., soft portions or specialized geometry).

For safety reasons, the entire movable assembly 16 preferably is enclosed within a stationary enclosure 40 formed of an opaque material, such as steel. The enclosure 40 is not shown in FIGS. 1, 3-5 to permit a fuller view of the movable assembly 16. The growing ribbon crystals 30 therefore extend upwardly, from the crucible, through a rubber light seal 41 and into the enclosure 40. FIG. 6 schematically shows additional details of the enclosure 40. Among other things, the enclosure 40 has manual controls 42 for controlling the interior components of the movable assembly 16, and an access door 44 with a viewport 46. The enclosure 40 also has a tool balancer 48 for balancing a trap door 50 that opens to permit removal of the tray 18.

As noted above, illustrative embodiments may use any of a number of different configurations for providing the laser beam 37. Those configurations can range from a single laser 38 shared across multiple furnaces 10, to a single furnace 10 having individual, stationary lasers 38 for each ribbon guide 14. The laser(s) 38 can be stationary, movable, and/or deliver their beams 37 through a movable delivery mechanism (e.g., a movable fiber optic cable) and/or through different media (e.g., through air).

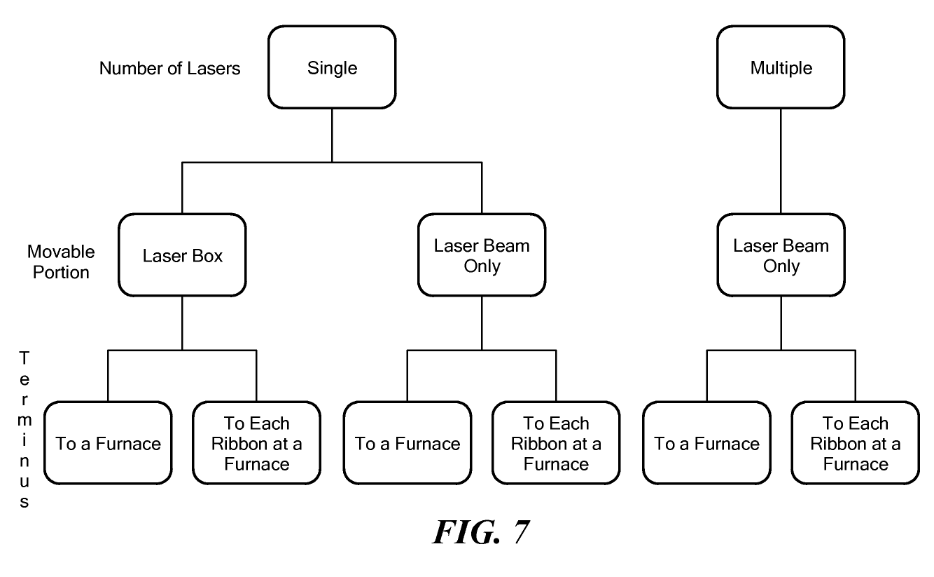

FIG. 7 generally shows a chart detailing various options for providing the laser beam 37. In summary, the three rows in the chart represent (from the top row to the bottom row):
number of lasers 38 in the system,
movable portion of the laser system, and
terminal point of the laser beam 37.

It should be noted that the chart is merely a menu of various possible options for delivering the laser beam 37. For example, the system may use a single laser 38, and only its beam 37 may be delivered to each of a plurality of different furnaces 10. A scanner 58 or other apparatus may deliver the laser beam 37 to the different channels in that furnace 10. As a second example, the system may have multiple lasers 38, and deliver the respective laser beams 37 to a furnace 10. Moreover, those skilled in the art can add further permutations that are not explicitly shown within this chart.

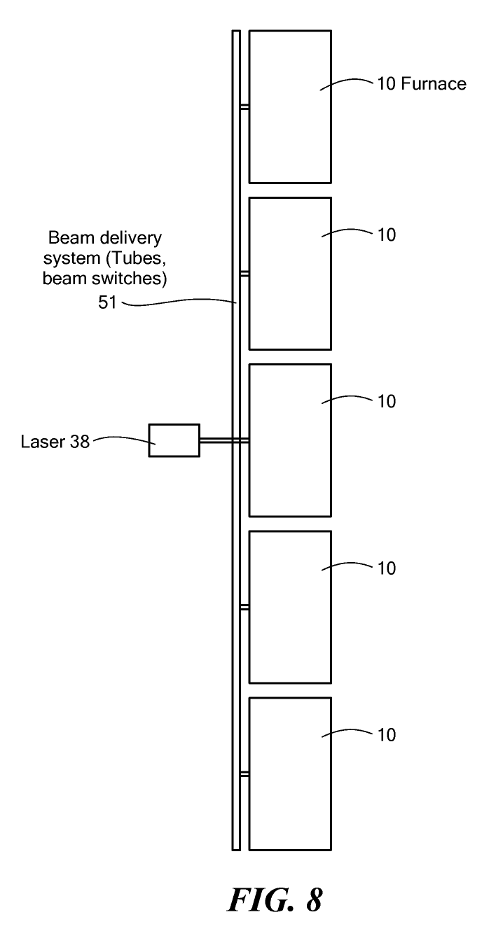

FIGS. 8-11 schematically show implementations of four different permutations/embodiments of the chart. It should be reiterated that these four permutations/embodiments are discussed for illustrative purposes only and thus, are not intended to limit all embodiments of the invention.

FIG. 8 schematically shows a system having five furnaces 10 that each share a laser beam 37 from a single, stationary laser 38. To those ends, the system of FIG. 8 also includes a tube 51 that acts as a transmission and switching medium through which the single laser beam 37 from the laser 38 travels. Each furnace 10 has a mirror box (not shown) at its intersection with the tube 51 for selectively reflecting the laser beam 37 into its interior. Each furnace 10 also has internal components for distributing the laser beam 37. For example, some furnaces may have a movable fiber optic head that distributes the laser beam 37, while other furnaces may have a similar tube and mirror box arrangement for distributing the laser beam 37.

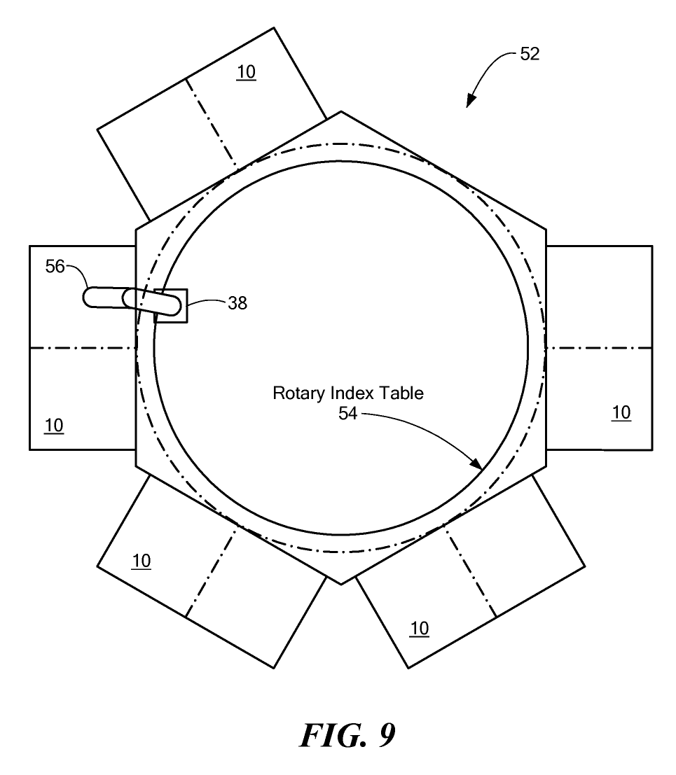

In a manner similar to the system shown in FIG. 8, the system in FIG. 9 services multiple furnaces 10. The system of FIG. 9, however, uses a rotating system 52 for servicing the furnaces 10. Specifically, in this embodiment, a single laser 38 is fixed on a rotary index table 54 that selectively moves to a selected furnace 10. A robotic arm 56 moves a fiber-optic cable (not shown) connected with the laser 38 to selective channels of each furnace 10. Alternatively, the robotic arm 26 may move the laser 38 itself to the various channels.

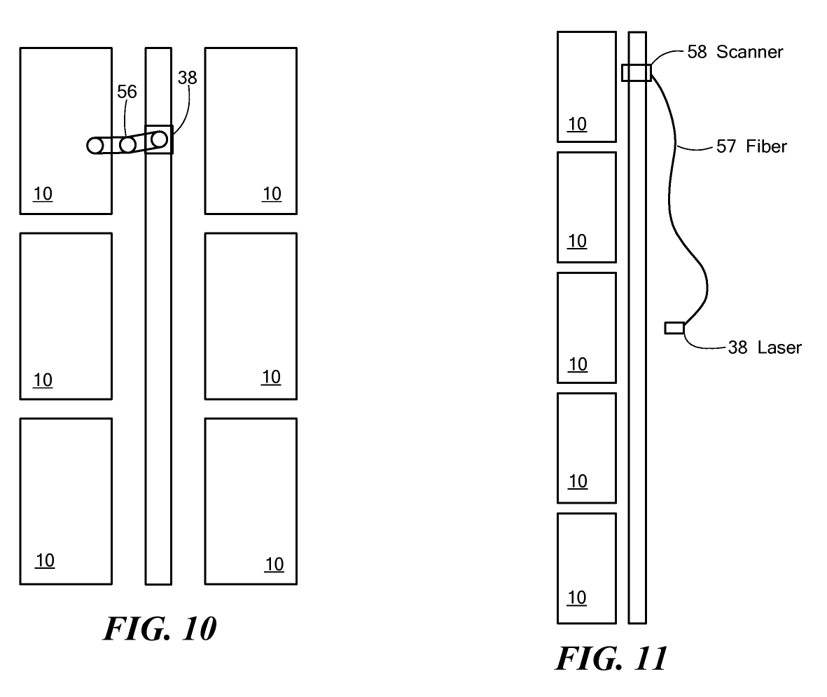

FIG. 10 schematically shows another embodiment of the invention that, in a manner similar to the embodiments shown in FIGS. 8 and 9, provides laser beams 37 for multiple furnaces 10. In fact, this embodiment is very similar to the embodiment shown in FIG. 9 by using a single, movable laser 38 with an attached fiber-optic cable (not shown). Unlike the embodiment shown in FIG. 9, however, the laser 38 in this embodiment moves linearly rather than rotationally.

FIG. 11 schematically shows yet another embodiment of the invention in which a single stationary laser 38 delivers laser beams 37 to multiple furnaces 10. To that end, this embodiment includes a fiber-optic cable 57 terminating at a scanner 58 that is linearly movable between different furnaces 10. Accordingly, the scanner 58 moves linearly to deliver the laser beam 37 to selected furnaces 10.

Of course, as noted above, the embodiments discussed above and shown in the various figures are illustrative and not intended to limit all embodiments invention.

Accordingly, illustrative embodiments of the invention enable silicon ribbon crystal-based wafers 31 to be continuously formed without interrupting the ribbon crystal growth process. The noted system overcomes various problems with prior art systems. Specifically, among other things, prior art manual scribing processes often create microcracks, while various embodiments, such as those using low power laser processes, substantially eliminate this problem. As a result, illustrative embodiments should improve wafer yield.

Also important is elimination of the manual operator from the production equation. More particularly, a ribbon crystal 30 and ribbon crystal-based wafer 31 essentially are very thin, brittle pieces of glass; a typical ribbon crystal 30, which can have portions as thin as about 100 microns or less, is extremely fragile. Despite the fact that only skilled, specially trained personnel typically participated in the process, their manual handling still often broke ribbon crystals 30 and wafers 31, thus lowering yield while increasing costs. Automated processing of such fragile crystals 30 and wafers 31, however, was considered impractical and a very complex design challenge, which led those in the art to use manual processes. The inventors thus discovered an effective automated mechanism for processing such fragile crystals 30 and wafers 31. Prototypes and furnaces in production similar to those described above have proven to more gently handle the ribbon crystals 30 and wafers 31 and thus, increased wafer yields while reducing labor costs.

Although the above discussion discloses various exemplary embodiments of the invention, it should be apparent that those skilled in the art can make various modifications that will achieve some of the advantages of the invention without departing from the true scope of the invention.

What is claimed is:

1. A furnace for growing a ribbon crystal, the furnace comprising:
a channel for growing a ribbon crystal at a given rate in a given direction; and
a separating mechanism for separating a portion from the growing ribbon crystal, at least part of the separating mechanism moving at about the given rate and in about the given direction while separating the portion from the growing ribbon crystal.

2. The furnace as defined by claim 1 wherein the separating mechanism comprises a fiber laser that produces a pulsed laser beam for cutting the growing ribbon crystal, the laser beam being part of the separating mechanism.

3. The furnace as defined by claim 1 wherein the separating mechanism comprises a laser beam directing apparatus for directing a laser beam toward the growing ribbon crystal, the laser beam being part of the separating mechanism.

4. The furnace as defined by claim 1 further comprising a plurality of channels for growing a plurality of ribbon crystals, the separating mechanism being movable to cut each of the plurality of ribbon crystals in substantially the same manner.

5. The furnace as defined by claim 1 wherein the separating mechanism comprises two areas for grasping the growing ribbon crystal, the separating mechanism separating the portion between the two grasping areas.

6. The furnace as defined by claim 1 wherein the separating mechanism comprises a movable arm for moving the separated portion of the ribbon crystal from a first location to a second location.

7. The furnace as defined by claim 1 wherein, in response to receipt of movement information relating to the given rate, at least part of the separating mechanism moves at about the given rate.

8. The furnace as defined by claim 1 further comprising a container for receiving the separated portion of the ribbon crystal.

9. The furnace as defined by claim 1 wherein the separating portion cuts the ribbon crystal as a function of the compression and tension of the growing ribbon crystal.

10. An apparatus for growing a ribbon crystal, the apparatus comprising:
a crystal growth channel;
a movable arm for grasping a ribbon crystal growing in the crystal growth channel; and
a laser separation apparatus for separating a portion from the growing ribbon crystal.

11. The apparatus as defined by claim 10 wherein the laser separation apparatus comprises a laser that generates a laser beam for cutting the portion of the growing ribbon crystal, the growing ribbon crystal moving at a given rate in a given direction, further wherein the laser beam moves at least at about the given rate in about the given direction when separating the portion from the growing ribbon crystal.

12. The apparatus as defined by claim 11 wherein the laser separation apparatus also moves at about the given rate and in about the given direction when separating the portion from the growing ribbon crystal.

13. The apparatus as defined by claim 10 wherein the laser separation apparatus comprises a low power fiber laser for generating a pulsed laser beam.

14. The apparatus as defined by claim 10 further comprising a plurality of ribbon guides for guiding a plurality of growing ribbon crystals, the laser separation apparatus being movable to each of the guides for cutting a plurality of growing ribbon crystals in substantially the same manner.

15. The apparatus as defined by claim 10 further comprising a container for receiving the portion of the growing ribbon crystal from the movable arm.

16. A method of forming a ribbon crystal-based wafer, the method comprising:
growing a ribbon crystal from a molten material;
using a separation mechanism for cutting the growing ribbon crystal to produce a separated portion; and
controlling a movable arm to move the separated portion to a receptacle.

17. The method as defined by claim 16 wherein the separation mechanism comprises a laser, the laser being used for cutting by generating a pulsed laser beam that traverses across the growing ribbon crystal a plurality of times.

18. The method as defined by claim 16 wherein using a separation mechanism comprises forming a generally linear cut line across the ribbon crystal between first and second suction devices.

19. The method as defined by claim 16 wherein growing comprises growing a plurality of ribbon crystals from molten material, the method further comprising:
detecting which of the plurality of ribbon crystals is at least a given length; and
serially moving the separation mechanism to each of a plurality of ribbon crystals determined to be at least the given length.

20. The method as defined by claim 16 wherein the separation mechanism produces a laser beam that moves in at least a first direction and a second direction, the first direction being across the width of the growing ribbon crystal, the second direction being substantially perpendicular to the first direction, the laser beam moving in the second direction at a rate that is substantially the same as the growth rate of the growing ribbon crystal in the second direction.

21. The method as defined by claim 16 wherein the growing ribbon crystal has a first portion under compression and a second portion under tension, the separation mechanism cutting substantially through the portion under compression before cutting the portion under tension.

22. An apparatus for growing a ribbon crystal, the apparatus comprising:
a plurality of channels for simultaneously growing a plurality of separate ribbon crystals;
a movable arm for grasping a growing ribbon crystal; and
a separation apparatus for separating a portion from at least one growing ribbon crystal, the separation apparatus being movable to process ribbon crystals at two or more of the channels.

23. The apparatus as defined by claim 22 wherein the separation apparatus comprises a laser apparatus.

24. The apparatus as defined by claim 23 wherein the laser apparatus comprises a pulsed laser.

25. The apparatus as defined by claim 23 further comprising:
position logic operatively coupled with the separation apparatus, the position logic being capable of detecting the position of at least one ribbon crystal, the separation apparatus being movable to process selected ones of the plurality of growing ribbon crystals in response to receipt of a signal from the position logic.
